(19) United States
(12) Patent Application Publication
(10) Pub. No.: US 2015/0202842 A1
(43) Pub. Date: Jul. 23, 2015

(54) Long-Lasting Antibacterial Metallic Surfaces and Methods for their Production

(71) Applicant: The University of Birmingham, Birmingham, West Midlands (GB)

(72) Inventors: Hanshan Dong, Birmingham (GB); Xiaoying Li, Birmingham (GB); Yangchun Dong, Birmingham (GB); Linhai Tian, Birmingham (GB)

(21) Appl. No.: 14/412,483

(22) PCT Filed: Jul. 2, 2013
(86) PCT No.: PCT/GB2013/051745

§ 371 Date: Jan. 2, 2015

(30) Foreign Application Priority Data
Jul. 5, 2012 (GB) 1211976.4

(51) Int. Cl. B32B 15/01; C23C 14/48; C23C 4/08; B32B 15/02; C23C 4/12

(52) U.S. Cl. CPC B32B 15/013; B32B 15/015; B32B 15/02; C23C 4/127; C23C 4/08; C23C 14/48; B32B 2307/536

(57) ABSTRACT

A method of modifying a surface characteristic of a stainless steel or cobalt-chromium (Co—Cr) based alloy article, comprising plasma surface co-alloying the article (such as by active screen plasma surface co-alloying), with both interstitial and substitutional alloying elements at a temperature in the range of from 300 to 600° C. and at a pressure of from 100 to 1500 Pa for 1 to 50 hours in an atmosphere comprising N-containing, C-containing or N/C-containing gas.

### FIELD

The invention relates to long-lasting anti-bacterial metallic surfaces, in particular to long-lasting anti-bacterial metallic surfaces comprising silver and/or copper doped superhard S-phase and to methods for producing the long-lasting anti-bacterial metallic surfaces.

### BACKGROUND

Silver (Ag) and its compounds are some of the strongest bactericides because biologically active silver ions can inactivate bacteria by interacting with thiol groups of bacterial proteins and enzymes [1]. The first documented use of silver as an antibacterial agent can date back to 1881 when silver nitrate was used for prevention of gonococcal ophthalmia neonatorun [2]. Silver has since been researched and as a result has found some applications such as Ag-containing PMMA bone cement, Ag-containing in dwelling catheters, wound dressings and stainless steel fixation devices [3, 4]. Similarly, copper (Cu) has also been used historically throughout the world as a hygienic material because Cu also has anti-microbial effects [5].

Currently there are two methods to form Ag or Cu-containing anti-bacterial surfaces on metallic materials by: (1) alloying bulk materials surface with silver and (2) coating the substrate with an Ag or Cu-containing composite thin layer. In the first approach, ion implantation is used to dope a metal surface with Ag or Cu [6]. However, the implanted surface layer is normally <0.5 μm and hence the durability is very poor due to unavoidable wear and tear in application. In addition, ion implantation is a line-of-sight process and hence it is difficult, if not impossible, to homogeneously treat components with complex 3-D shapes.

The second approach, Ag-containing coatings, is the most researched method and some commercial processes, such as AgION™, are available to coat stainless steel surfaces. However, the AgION™ is essentially an Ag-doped polymer coating and therefore it is designed for non-tribological applications with poor durability [7]. Attempts have been made by some researchers to produce Ag or Cu-ceramic composite coatings to increase wear resistance such as PACVD deposited thin Ag-DLC composite coating [8] or thermal sprayed Ag—TiO₂ composite coating [9]. However, the antibacterial effect of such thin coatings cannot last long mainly due to their low load-bearing capacity and the expected short durability; the durability of antibacterial effect of sprayed coatings is limited by their porous nature and very low bonding to the substrate. Failure of such coatings will lead to fast leaching of Ag or Cu ions and the resulted detrimental toxic effect.

It is an object of the present invention to develop novel surface engineering technologies, which can enable the above-mentioned disadvantages to be obviated or mitigated, to generate highly effective, long-lasting and minimal leaching antimicrobial metallic surfaces. This has been achieved by plasma surface co-alloying (for example by active screen plasma co-alloying) with interstitial elements (such as N, C or N/C) to form hard and wear resistant S-phase and with substitutional elements (such as Ag, Cu or Ag/Cu) to form an anti-bacterial agent reservoir for slow and continual release of Ag, Cu or both Ag and Cu for prolonged antimicrobial effect.

### DESCRIPTION OF THE INVENTION

Broadly considered, the present invention provides novel plasma surface engineering technologies based on simultaneous surface co-alloying of stainless steel and Co—Cr alloys with both substitutional (such as Ag, Cu etc.) and interstitial (such as C, N etc.) alloying elements for the generation of novel multifunctional surfaces with high hardness, high wear resistance, good corrosion resistance and long-lasting and high antibacterial efficacy. The novel long-lasting anti-bacterial stainless steel surfaces can be used for medical devices (such as medical instruments and implants) to prevent post-operation infection, for hospital equipment to avoid hospital acquired infection and for food processing facilities to reduce food poison as well as for kitchen wares to improve hygiene.

Plasma surface alloying has been used for more than 20 years to enhance the surface properties of ferrous materials. Recently, low-temperature plasma surface alloying of austenitic stainless steels and Co—Cr alloys with such interstitial alloying elements as carbon and nitrogen has been shown to achieve improvement in the combined properties of corrosion, wear and fatigue through the formation of interstitial highly supersaturated expanded austenite, i.e. S-phase [10]. This S-phase layer is very hard (800-1200HV) and wear resistant resulting in high durability under wear conditions. Therefore, S-phase layer could be an ideal substrate for long-lasting antimicrobial surfaces. However, it is almost impossible to generate an effective antimicrobial surface layers using conventional DC or RF plasma surface alloying with Ag and/or Cu because it is impossible to form a stable Ag/Cu plasma at temperatures below 450° C. and the diffusion of substitutional Ag/Cu elements is very slow at such low-temperature.

An advanced active screen plasma (ASP) technology (FIG. 1) has become available in which substantially the entire workload is substantially surrounded by a metal screen, on which a high voltage cathodic potential is applied and the plasma forms (hence the term “Active Screen” is used). The parts to be treated are placed at floating potential or subjected to a relatively low bias voltage. The plasma formed on the screen contains a mixture of metal ions, electrons and other active species, which are then encouraged to flow through the screen and over the workload by a specially designed gas flow and/or electric field (if a bias is applied). Recent research by the inventors has found that ‘sputtering and redeposition’ is a dominant mass transfer mechanism [11]. For example, during the active screen plasma nitriding process using a steel mesh screen, N⁺ ions from plasma near the screen are accelerated to strike the cathodic metal screen surface and thus detach or sputter steel atoms into the plasma to form FeN particles, which are then deposited onto parts surface. Subsequently, the deposited FeN is decomposed into Fe₂₋₃N and Fe₄N and the active nitrogen atoms thus released diffuse into a stainless steel or Co—Cr alloy surface to form N or C S-phase if low-temperature is used.

According to the present invention, there is provided a method of co-alloying stainless steel or Co—Cr alloy surfaces simultaneously with (i) N, C or C/N to form hard and wear/corrosion resistant S-phase and (ii) interstitial and substitutional alloying elements, typically with Ag, Cu or Ag/Cu to confer anti-bacterial effect, for example, by modifying plasma surface technology, such as ASP technology, with a purpose designed composite or hybrid metal screen comprising stainless steel or Co—Cr alloy mesh mixed with Ag, Cu or Ag/Cu at a temperature in the range of from 300 to 600° C. and at a pressure of from 100 to 1500 Pa for 1 to 50 hours in an atmosphere comprising N-containing, C-containing or C/N-containing gases.

Stainless steels typically have a minimum of 11 weight % chromium by mass. The chromium typically forms a passive film of chromium oxide which blocks corrosion from spreading into the metals internal structure. Typically at least 13% or up to 26% chromium is used.

The stainless steel may be ferritic or martensitic but is typically austentistic. Nickel may be added to stablise the austentistic structure of iron in the steel. Manganese may also be added to the stainless steel. Duplex stainless steels containing a mixed microstructure of austenite and ferrite may be used.

Such stainless steels are generally known in the art.

Cobalt-chrome alloys typically have high strength and may be used in gas turbines, dental implants and orthopaedic implants. Typically they have cobalt with 27 to 30 weight % chromium, 5 to 7 weight % molybdenum, less than 1% iron, less than 0.75% nickel and limits on other elements such as manganese, silicon, carbon, nitrogen, tungsten, phosphorous, sulphur and boron. The industry standard is ASTM-F75 or ASTM-F799.

The surface characteristic to be modified by the method of the present invention may be any one or more of hardness, wear resistance, corrosion resistance, fatigue strength and high anti-bacterial efficacy.

Preferably, said composite or hybrid metal screen, whole screen or part of a screen, comprises stainless steel (for surface treatment of stainless steel articles) or Co—Cr alloy (for surface treatment of Co—Cr articles) and 10-70 wt % Ag, Cu or both Ag and Cu, and may be made by hot isostatic pressing (HIPping) of stainless steel or Co—Cr micro powders with Ag/Cu nano powders at temperature between 700 and 1000° C. under a pressure of 60-120 MPa for 1-5 hours followed by machining if necessary.

Alternatively, said composite or hybrid metal screen comprising stainless steel (for surface treatment of stainless steel articles) or Co—Cr alloy (for surface treatment of Co—Cr articles) and 10-70 wt % Ag, Cu or both Ag and Cu, may be made by weaving austenitic stainless steel or Co—Cr alloy and Ag/Cu strips or by wiring austenitic stainless steel or Co—Cr alloy mesh with Ag/Cu strips.

Alternatively, a biased target source comprising Ag, Cu or Ag/Cu may be introduced into typical active-screen plasma equipment as an additional source cathode (FIG. 2). The substitutional elements from both the screen (made from the substrate material) and the source (Ag, Cu or Ag/Cu) will be sputtered out and deposited onto the surface of the parts; in the meantime, interstitial elements (N, C or N/C) diffuse into the deposited nanocomposite and the substrate. Thus, a long-lasting anti-bacterial stainless steel or Co—Cr alloy surface with varying percentage of Ag, Cu or Ag/Cu can be generated by adjusting the bias applied to the additional source cathode.

Preferably, said article is a medical implant, such as a joint or knee prosthesis, in which case said plasma treating is preferably carried out at a temperature in the range of from 350 to 550° C., and more preferably 400 to 500° C. At these temperatures, the method generally confers anti-bacterial efficacy, increases wear resistance and enhances corrosion resistance.

Alternatively, said article may be a medical tool (such as surgical or dental tool) or component for food processing and hospital facilities, in which case said plasma treating is typically carried out at a temperature in the range of from 350 to 550° C., more typically 400 to 500° C. At these temperatures, the method generally confers high anti-bacterial efficacy, significantly increase wear resistance but not necessarily corrosion resistance.

Typically, said treatment pressure is in the range of from 400 to 600 Pa and is more typically about 500 Pa; the duration of said treatment is in the range of from 1 to 50 hours and more typically 5 to 30 hours.

Typically, the plasma treatment is carried out in the presence of at least one unreactive gas, for example selected from hydrogen, helium, argon or other noble gas. As used herein “unreactive” relates to a gas which does not become incorporated into the article to any significant extent.

Typically, the plasma treatment is carried out in the presence of at least one reactive gas, such as an N-containing gas (e.g. N₂ or ammonia) or a C-containing gas (e.g. CO or CH₄). As used herein “reactive” relates to a gas which (or a part of which) does become incorporated into the article to a certain extent. Where an N-containing gas is used, the plasma treating step is typically effected at a temperature of from 350 to 450° C.

Particularly preferred gas mixtures are hydrogen and methane for carburising, nitrogen and hydrogen for nitriding, and methane, nitrogen and hydrogen for nitrocarburising.

Typically, the or each carbon-containing gas constitutes from 0.5 to 20% by volume of the total atmosphere. Typically, said reactive gas (when present) constitutes from 0.5 to 10% by volume of the total atmosphere.

Typically, the or each N-containing gas constitutes from 10 to 40% by volume of the total atmosphere. Preferably, said N-containing gas (when present) constitutes from 20 to 30% by volume of the total atmosphere. Typically the concentration of the N- or C-containing gas is substantially homogenous across the chamber.

Typically, the or each C-containing gas constitutes from 0.5 to 10% by volume of the total atmosphere. Preferably, said C-containing gas (when present) constitutes from 1 to 5% by volume of the total atmosphere.

The present invention also resides in a surface-alloyed stainless steel or cobalt-chromium based article producible or obtainable by the method of the present invention, said article characterised by having a surface region comprising (i) a thin S-phase layer embedded by Ag-, Cu or Ag/Cu and (ii) a thicker S-phase case. Preferably, said surface region has a thickness in the range of from 1 to 50 μm.

Composite or hybrid screens for use in the invention and ASP devices containing them are also published.

### BRIEF DESCRIPTION OF THE DRAWINGS

Embodiments of the present invention will now be described by way of example only, with reference to the accompanying drawings and specific examples hereafter.

FIG. 1 is a schematic view of an active screen plasma unit with composite or hybrid metal screen in which the co-alloying described in the preferred embodiments below was effected,

FIG. 2 is a schematic view of an active screen plasma unit with an additional source cathode in which the co-alloying described in the preferred embodiments below was effected,

FIG. 3 shows SEM micrographs of the cross-sectional microstructure of a 316 L test piece co-alloyed with Ag and nitrogen in accordance with the present invention,

FIG. 4 shows depth distribution of (a) Ag and (b) N in 15-h active-screen Ag and N co-alloyed (nitro-silvered) 316 L test piece as a function of treatment temperature,

FIG. 5 is (A) TEM micrograph and (B) SAD patterns showing nano Ag particles embedded in S-phase layer in AS plasma nitro-silvered 316LVM surface; TEM micrograph (C) showing nano Cu particles embedded in S-phase layer in AS plasma nitro-coppered 316LVM surface,

FIGS. 6-8 are graphs showing the hardness and wear resistance of untreated test pieces and test pieces surface hardened in accordance with the present invention:

FIG. 6 Effect of treatment parameters on the microhardness of LTASDP nitropsilvered 316LVM surface.

FIG. 7 Wear rate and wear depth of wear track on LTASP intro-silvered 316LVM surface.

FIG. 8 Wear rate of the LTASP nitrocoppered (CuNSS) 316,316LVM and High-N 316 surfaces as comparison with untreated stainless steels.

FIGS. 9-11 are graphs showing the anti-bacterial properties of untreated test pieces and test pieces surface hardened in accordance with the present invention:

FIG. 9 E. coli spread plate results of:

(a) control of single S phase layer (NSS), (b) AgNSS 400 400/15, and (c) AgNSS 450/15.

FIG. 10 Reduction rate of E. coli and S. epidermidis on LTASP nitro-coppered CuNSS, LTASP nitrided NSS and control (coverslip).

FIG. 11 Reduction percentage of bacteria on circularly washed steels.

Typical examples of suitable stainless steel and Co—Cr based alloys which are susceptible to the process of the present invention are summarised in Table 1. The stainless steel and Co—Cr based alloys of which the article is formed may be in the wrought, cast or PM/HIP form before the article is subjected to the process to the present invention.

TABLE 1
Examples of useful stainless steel and Co—Cr alloys

| | | | | | | | | | | |
|---|---|---|---|---|---|---|---|---|---|---|
| Materials | Cr | Mo | Ni | W | C | Si | Mn | Fe | Co | others |

AISI300 austenitic stainless steels

| | | | | | | | | | | |
|---|---|---|---|---|---|---|---|---|---|---|
| 304 | 19-21 | — | 8-12 | — | <0.08 | 1 | 2 | bal | — | |
| 310 | 24-26 | — | 19-22 | — | <0.25 | 1.5 | 2 | bal | — | |
| 316 | 16-18 | 2-3 | 10-14 | — | <0.08 | 1 | 2 | bal | — | |
| 316L | 16-18 | 2-3 | 10-14 | — | <0.03 | 1 | 2 | bal | — | |
| 321 | 17-19 | — | 9-12 | — | <0.08 | 1 | 2 | bal | — | >(5x%C)Ti |

Medical grade austenitic stainless steels

| | | | | | | | | | | |
|---|---|---|---|---|---|---|---|---|---|---|
| F138 (LVM) | 17-19 | 2-3 | 13-15 | — | <0.03 | <0.75 | <2 | bal | — | <0.1N |
| F2581(Ni-free) | 16-18 | 3-4 | <0.05 | — | <0.25 | <0.6 | 10-13 | bal | — | 0.45-0.55N |
| F1586 (high-N) | 20-22 | 2-3 | 9-11 | — | <0.08 | <0.75 | 2-4 | bal | — | 0.25-0.50N |

Medical grade Co—Cr alloys

| | | | | | | | | | |
|---|---|---|---|---|---|---|---|---|---|
| F75 | 27-30 | 5-7 | <1 | — | <0.35 | <1 | <1 | <0.75 | bal |
| F799 | 26-30 | 5-7 | <1 | — | <0.35 | <1 | <1 | <1.5 | bal |
| F90 | 19-21 | — | 9-11 | 13-16 | <0.15 | <0.4 | 1-2 | <3 | bal |
| F562 | 19-21 | 9-11 | 33-37 | — | <0.15 | <0.15 | <0.15 | <1 | bal |

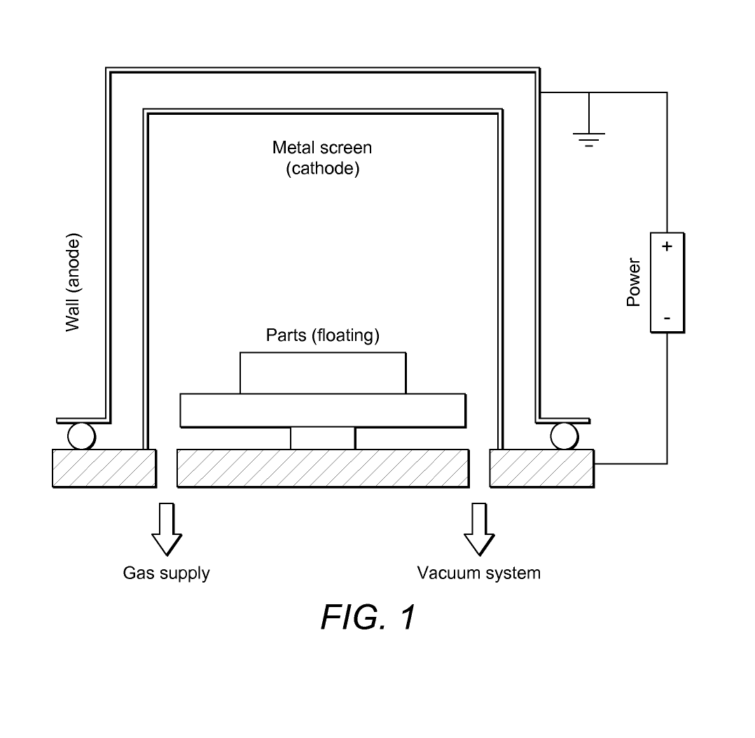

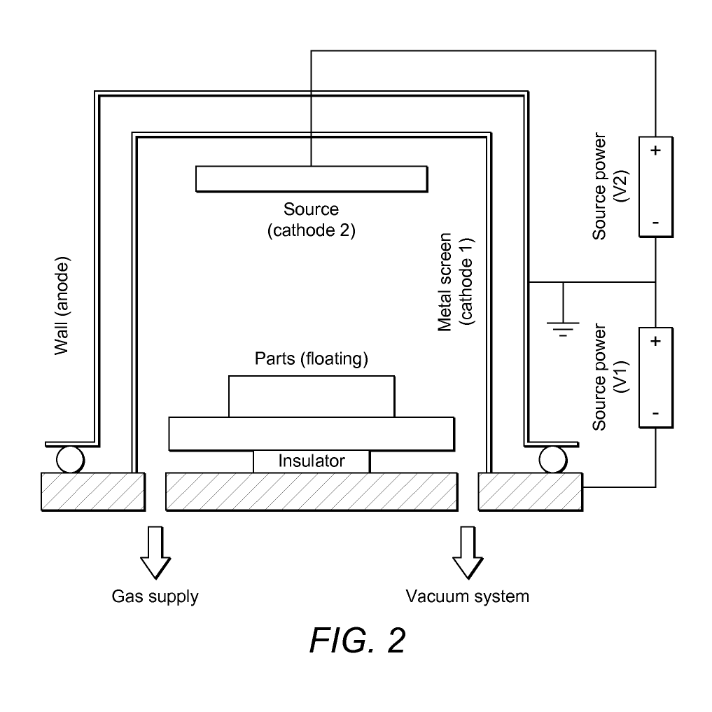

In order to demonstrate the advantages of the present invention, three austenitic stainless steels, 316, 316LVM and high-N, were co-alloyed with nitrogen and Ag (nitro-silvering) or Cu (nitro-coppering) in accordance with the present invention using an active-screen plasma apparatus shown in FIG. 1. The apparatus comprises a sealable vessel (anode), a vacuum system with a rotary pump (not shown), a dc power supply, a gas supply system, a temperature measurement system (not shown), a stainless steel mesh screen containing silver or copper as the composite cathode screen (active screen), and a work table at a floating potential (i.e. zero bias) for supporting articles to be treated.

The treatment parameters and the sample codes are summarised in Table 2. To produce control samples, a conventional active screen plasma facility with a stainless steel mesh cylinder was also used for the low-temperature plasma nitriding (LTPN) of austenitic stainless steel surface without any antimicrobial agent (see NSS in Table 2). The articles were then subjected to SEM and TEM analysis for metallography analysis and phase identification, glow discharge spectrometry (GDS) analysis for chemical composition determination, surface hardness measurements, wear tests and antibacterial tests.

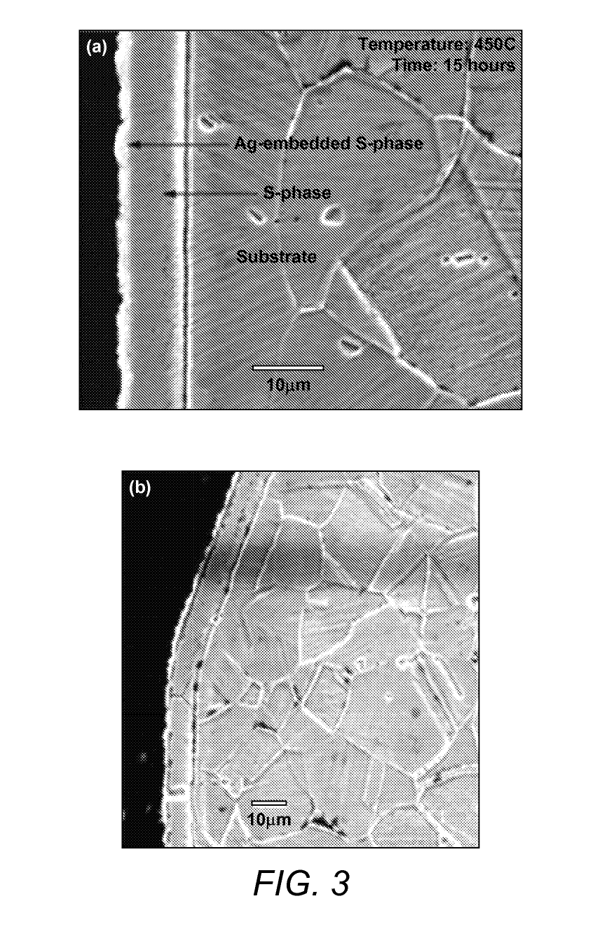

The cross-sectional micrographs in FIG. 3 show the typical appearance of the layers from surface to substrate produced by active screen plasma (ASP) co-alloying. It can be seen that the surface of steel had been significantly changed when it was treated at 450° C. for 15 hours, i.e. a double-layer was formed over the austenitic substrate. The double-layer surface comprised a white layer at the surface with a thickness of about 0.8-1.0 μm, and a thick zone between the white layer and substrate with a thickness of 10 μm (FIG. 3a). The zone appeared smooth and featureless in morphology, and contained no visible grain boundaries inside the layer. It can be seen that the double-layer structure homogeneously covered the whole sample surface, as shown in FIG. 3b. The steels treated at 400 and 500° C. for 15 h and at 450° C. for 20 h were also cross sectioned and examined microscopically. The surface white layer appeared to be uniform (˜1 μm) regardless of increasing temperature.

TABLE 2
Examples of treatment parameters and sample codes

| | Screen (%) | | | Gas (%) | | Time | Temp. | | |
|---|---|---|---|---|---|---|---|---|---|
| Code | ASS | Ag | Cu | H₂ | N₂ | h | ° C. | Substrate | Note |
| NSS | 100 | 0 | 0 | 75 | 25 | 15 | 450 | 316LVM | Control |
| AgNSS 400/15 | 40 | 60 | 0 | 75 | 25 | 15 | 450 | 316LVM | Nitro- |
| AgNSS 450/15 | 40 | 60 | 0 | 75 | 25 | 15 | 450 | 316LVM | silvering |
| AgNSS 450/20 | 40 | 60 | 0 | 75 | 25 | 20 | 450 | 316LVM | |
| AgNSS 500/15 | 40 | 60 | 0 | 75 | 25 | 15 | 450 | 316LVM | |
| CuNSS_25 | 40 | 0 | 60 | 75 | 25 | 15 | 450 | * | Nitro- |
| CuNSS_75 | 40 | 0 | 60 | 25 | 75 | 15 | 450 | * | coppering |

NB: * 316, 316LVN or high-N

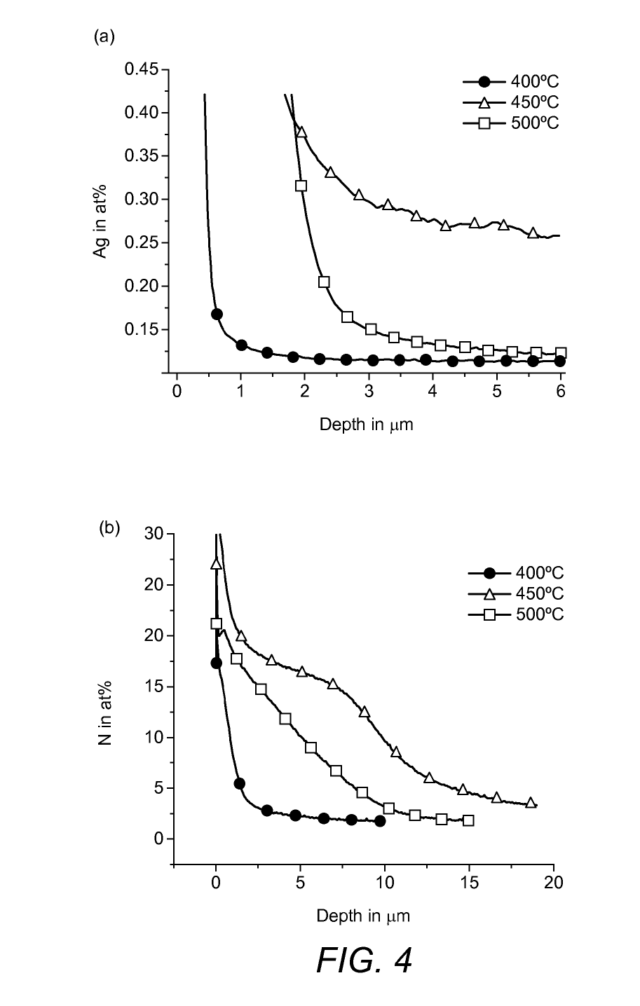

FIG. 4 shows typical GDOES elemental depth profiles of Ag and N and the influences of treatment temperature on the elemental distribution of Ag and N through the multilayers. It can be seen that the N depth profile exhibited a plateau type shape with steep leading edges, while Ag depth profile exhibited similar shape but with a much smaller thickness. The thickness of the Ag rich layer appeared to be constant at 1 μm regardless of the increase in temperature, whereas N was significantly affected by the treatment, i.e. when steel was treated at 400° C., diffusion depth of N was very small (<5 μm). But when temperature increased to 450° C., nitrogen diffusion depth increased from less than 5 μm to 15 μm as defined by GDOES. When temperature further increased to 500° C., nitrogen depth decreased again from 15 μm down to about 12 μm and the N concentration decreased more rapidly than that for the steel treated at 450° C.

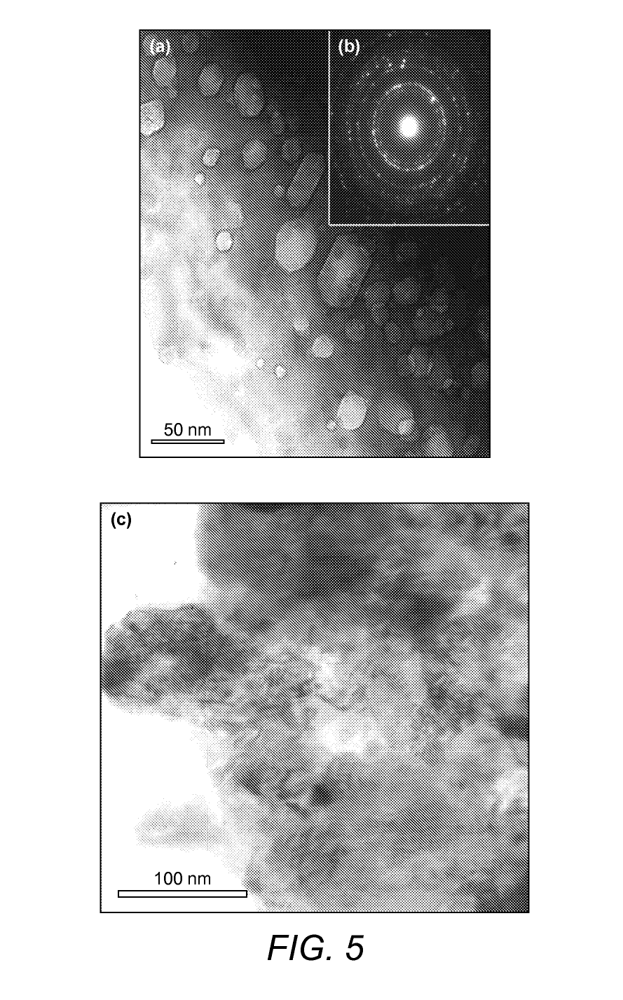

XRD analysis revealed Ag and S-phase peaks from the ASP nitro-silvered 316LVM surfaces and Cu and S-phase peaks from the ASP nitro-coppered 316LVM surfaces. TEM studies confirmed that the multilayer structure produced by low temperature ASP nitro-silvering and nitro-coppering consisted of nano crystalline Ag (FIG. 5 A) and Cu respectively embedded in S-phase (FIG. 5C).

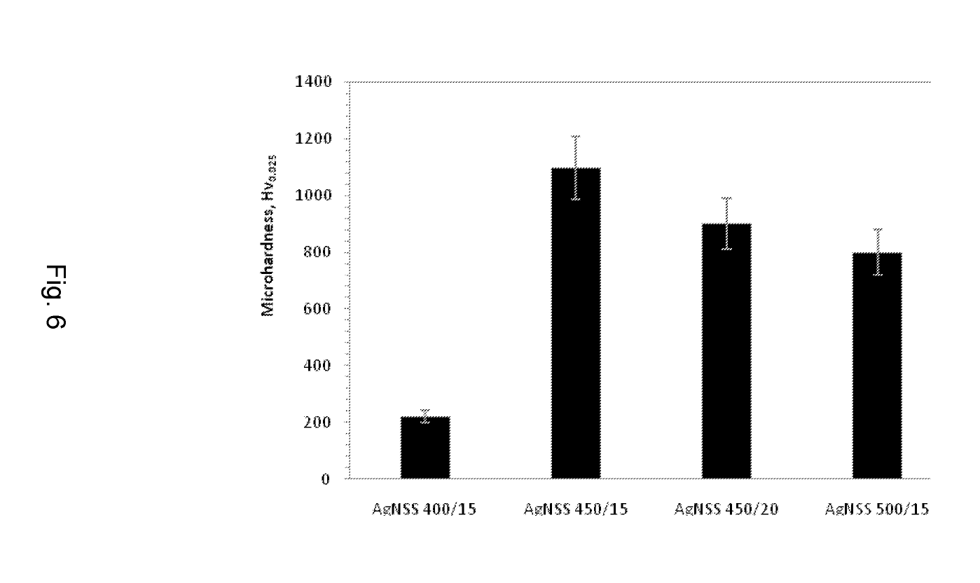

The effect of the treatment conditions on surface microhardness profiles are depicted in FIG. 6. It is clear that 450° C. ASP nitro-silvered specimens produced effective hardening up to 800-1000 HV0.025. The steel treated at 400° C. showed a low hardness with value of 220 HV0.025 very similar to the untreated steel. The surface hardness of the 450° C. ASP nitro-coppered CuNSS_{—}25 and CuNSS_{—}75 is about 1200 HV0.025.

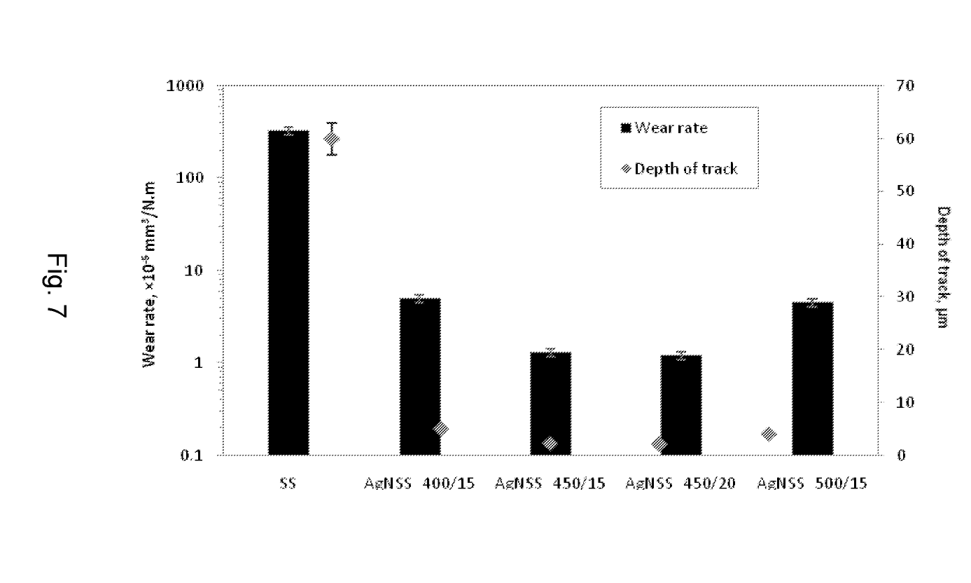

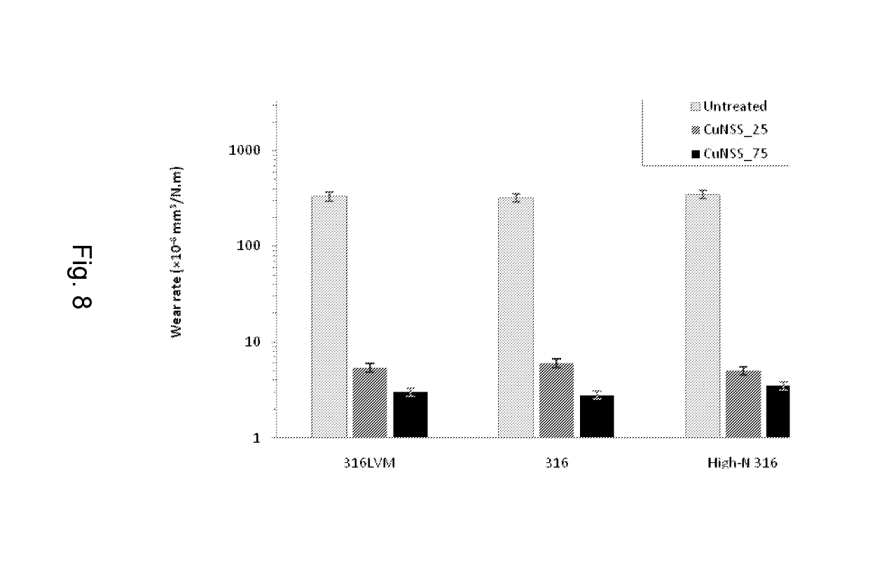

FIG. 7 compares the wear properties of ASP nitro-silvered stainless steel treated at 400, 450 and 500° C. Wear resistance of AgNSS 450/15 was improved by more than two orders of magnitude compared with the untreated SS sample. Judging from the wear track depth, the Ag-rich layer was unlikely to have been completely worn off after completion of the wear test. Similar improvement has also been achieved by ASP nitro-coppering for three medical grade ASSs (FIG. 8).

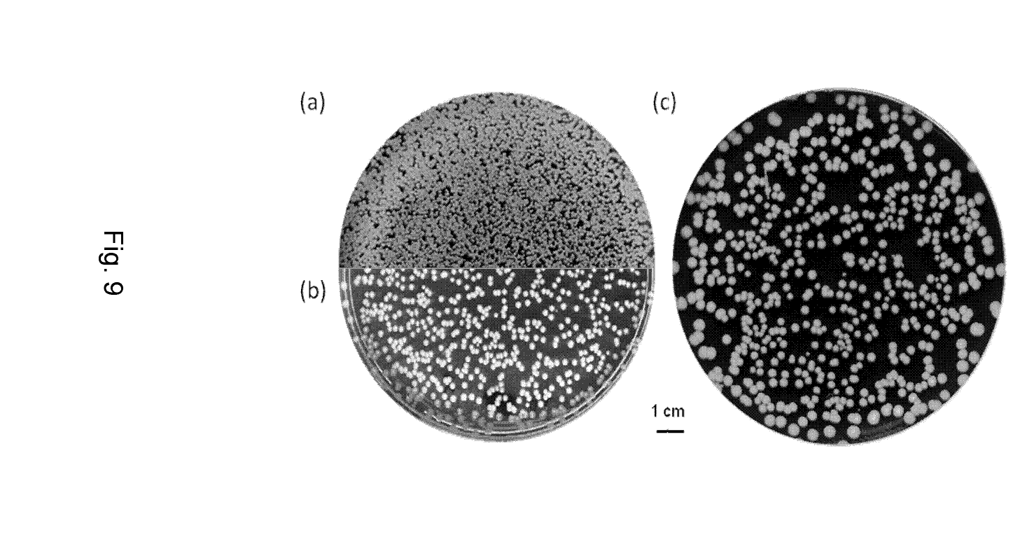

The in vitro antibacterial behaviours of stainless steel surfaces co-alloyed with Ag and N (nitro-silvering) or with Cu and N (nitro-coppering) were evaluated. The cover slip was used as control and the NSS was used as control of Ag-free or Cu-free (i.e. S-phase only). FIGS. 9(a) and (b) show two halves of two separate Petri dishes covered with bacteria of E. coli. FIG. 9(a) is from specimen with S-phase only (NSS) and (b) is from AgNSS 400/15. They both are controls for comparison with the steel alloyed with AgNSS 450/15 (c). It can be seen that the dish (a) was almost completely covered by bacterial colonies where as on (b) and (c) there were few. Colonies shown in (b) and (c) were larger because there was less competition for nutrients when fewer bacteria were present.

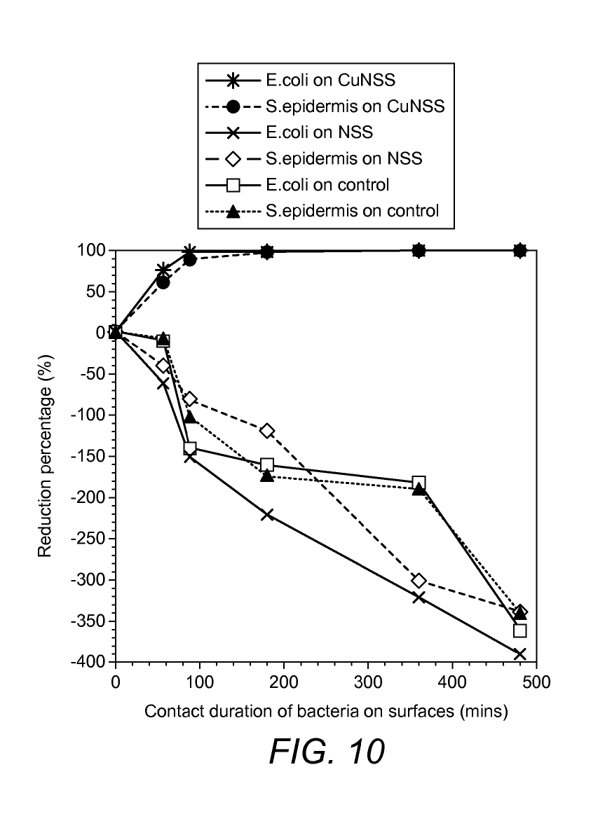

The ASP nitro-coppered CuNSS surface was very effective in inhibiting many spectrums of bacteria, quickly and thoroughly. FIG. 10 shows the reduction rate of gram negative E. coli and gram positive S. epidermidis on CuNSS. Compared with the Cu-free NSS and cover slip controls, there was significant difference. After 180 mins (3 h), more than three-fold rises of bacterial number on the NSS and control surfaces were found, but no viable cells were detected on the CuNSS (killing percentage of 100%). It is worth noting that there was a difference between the reduction rate of E. coli and S. epidermidis on the surface of CuNSS: the E. coli reduced by 75% and 98%, respectively, after 60 mins and 90 mins, whereas the S. epidermidis cells reduced by 60% and 90% respectively.

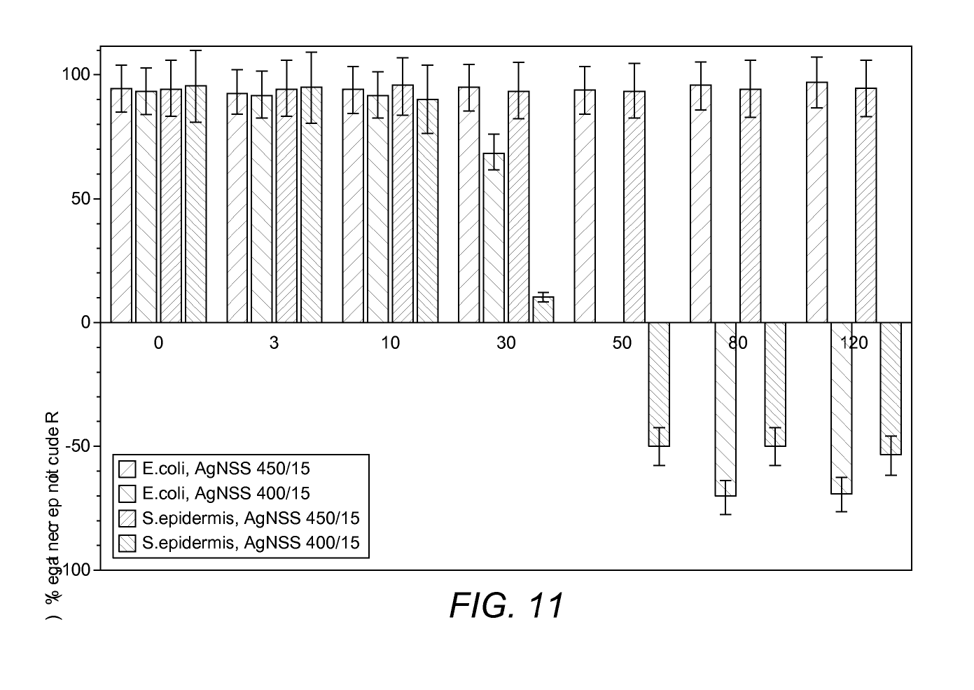

To evaluate the in vitro durability of antibacterial activity of alloyed surfaces, dynamic susceptibility observation was accomplished using system washing and sterilizing that corresponded to hospital routine cleaning, and spread plate tests were carried out at intervals to evaluate viability. The antibacterial properties of surfaces after 3, 10, 30, 50, 80 and 120 times of test-cleaning cycles are shown in FIG. 11. In the first 10 cycles, two groups of samples kept high antibacterial activity and the bacterial reduction of E. coli balanced at 92%. After around 50 cycles, the silver activity of AgNSS 400/15 was not maintained and the killing percentage of E. coli and S. epidermidis dropped to 70% and 50%, respectively. In contrast, AgNSS 450/15 maintained at 92%, 92% and 95% after 10, 50, 80 intervals, and after the final cycle, the average reduction percentages of E. coli and S. epidermidis cells were retained at 96% and 94% respectively.

### REFERENCES

1 Q. L. Feng et al., Journal Biomaterials Research, 52(2000), 662-668.
2 C. Credé, Die Verhütung der Augenentzundung der Neugeborenen, Archiv für Gynaekologie, 17(1881), 50-53.
3 D. W. Brett, A discussion of silver as an antimicrobial agent, Ostomy Wound Management, 52 (2006), 34-41.
4 M. Bosetti, A. Masse, E. Tobin and M Cannas, Silver coated materials for external fixation devices, in vitro biocompatibility and genotoxicity, Biomaterials, 23 (2002), 887-892.
5 R. Duguid, Copper-inhibition of the growth of oral streptococci and actinomyces Biomaterials, 4 (1983), 225-7.
6 Y. Z. Wan, S. Raman, F. He and Y. Huang, Surface modification of medical metals by ion implantation of silver and copper, Vacuum, 81(2007), 1114-8.
7 M M Cowan et al., Antimicrobial efficacy of a silver-zeolite matrix coating on stainless steel, Journal of Indutrial Microbiology and Biotechnology, 30(2003), 102-106.
8 F. R. Marciano et al, Antibacterial activity of DLC and Ag-DLC films produced by PECVD technique, Diamond and Diamond Related Materials, 18(2009), 1010-1014.
9 B. Li et al., Preparation and anti-bacterial properties of plasma sprayed nano-titania/silver coatings, Materials Chemistry and Physics, IIII
10 H. Dong, S-phase engineering of Fe—Cr, Co—Cr and Ni—Cr alloys, International Materials Review, 55(2010), 65-98.
11 S. Comjeira Gallo, H. Dong, Vacuum, 84 (2010), 321-325.

1-29. (canceled)

30. A method of modifying a surface characteristic of a stainless eel or cobalt-chromium (Co—Cr) based ahoy article, comprising:
plasma surface co-alloying the article, with both interstitial and substitutional alloying elements at a temperature in the range of from 300° C. to 600° C. and at a pressure of from 100 Pa to 1500 Pa for 1 hour to 50 hours in an atmosphere comprising N-containing, C-containing or N/C-containing gas, wherein a biased target source comprising Ag, Cu or Ag/Cu is introduced as an additional source cathode to achieve varying percentages of Ag, Cu or Ag/Cu by adjusting the bias applied to the additional source cathode.

31. The method of claim 30, wherein the interstitial alloying element is N, C or both N and C for forming hard and wear/corrosion resistant S-phase and the substitutional alloying element is Ag, Cu or both Ag and Cu for conferring anti-bacterial efficacy.

32. The method of claim 30, wherein the surface characteristic to be modified is one or more of hardness, wear resistance, corrosion resistance, fatigue strength and antibacterial property.

33. The method of claim 30, wherein the active screen plasma unit contains a composite or hybrid metal screen such as a whole screen or part of a screen, comprising stainless steel mesh or Co—Cr alloy mesh mixed with Ag, Cu or both Ag and Cu at a concentration ranging from 10 to 70 wt %.

34. The method of claim 33, wherein the composite or hybrid metal screen is made by hot isostatic pressing (HIPping) of stainless steel or Co—Cr micro powders with Ag/Cu nano powders at temperature between 700° C. and 1000° C. under a pressure of 60 MPa to 120 MPa for 1 hour to 5 hours.

35. The method of claim 33, wherein the composite or hybrid metal screen is made by weaving austenitic stainless steel or Co—Cr alloy and Ag/Cu strips or by wiring austenitic stainless steel or Co—Cr alloy mesh with Ag/Cu strips.

36. The method of claim 30, wherein a biased target source comprising Ag, Cu or Ag/Cu is introduced as an additional source cathode to achieve varying percentages of Ag, Cu or Ag/Cu by adjusting the bias applied to the additional source cathode.

37. The method of claim 1, wherein the article whose surface characteristic is to be modified is a medical implant, such as a joint or knee prosthesis.

38. The method of claim 1, wherein the article whose surface characteristic is to be modified is a medical tool or component for food processing and hospital facilities.

39. The method of claim 1, wherein the plasma surface co-alloying is carried out at a temperature in the range of from 400° C. to 650° C.,

40. The method of claim 39, wherein the plasma surface co-alloying is carried out at a temperature in the range of from 450° C. to 550° C.

41. The method of claim 1, wherein the plasma surface co-alloying is carried out at a pressure in the range of from 400 Pa to 600 Pa.

42. The method of claim 1, wherein the duration of the plasma surface co-alloying is in the range of from 5 hours to 30 hours.

43. The method of claim 1, wherein the plasma surface co-alloying is carried out in the presence of at least one unreactive gas selected from hydrogen, helium, argon or other noble gas.

44. The method of claim 1, wherein the plasma surface co-alloying is carried out in the presence of at least one reactive gas.

45. The method of claim 44, wherein the reactive gas is a nitrogen containing gas, a carbon containing gas, or a mixture thereof.

46. The method of claim 44, wherein said reactive gas constitutes from 0.5 to 30% by volume of the total atmosphere.

47. The method of claim 44, wherein the reactive gas is methane, and wherein the plasma surface co-alloying is carried out in the presence of at least one unreactive gas selected from hydrogen or a mixture of hydrogen and argon.

48. The method of claim 1, wherein the reactive gas constitutes from 0.5 to 20% by volume of the total atmosphere.

49. A surface-hardened stainless steel or Co—Cr alloy based article obtainable by the method of claim 1, said article characterized by a surface region comprising:
(i) a thin S-phase surface layer embedded by Ag-, Cu or Ag/Cu, and
(ii) a thicker subsurface S-phase case.

50. The article of claim 26, wherein said surface region including a surface S-phase layer embedded by by Ag-, Cu or Ag/Cu and a subsurface S-phase case has a thickness in the range of from 1 to 50 μm.

51. A composite or hybrid metal screen for use in active screen plasma co-alloying according to claim 1, obtainable by hot isostatic pressing of stainless steel or Co—Cr micro powders with Ag/Cu nano powders at temperature between 700 and 1000° C. under a pressure of 60-120 MPa for 1-5 hours.

52. A composite or hybrid metal screen for use in active screen plasma co-alloying according to claim 1, obtainable by weaving austenitic stainless steel or Co—Cr alloy and Ag/Cu strips or by wiring austenitic stainless steel or Co—Cr alloy mesh with Ag/Cu strips.
